(19) United States
(12) Patent Application Publication
(10) Pub. No.: US 2026/0101455 A1
(43) Pub. Date: Apr. 9, 2026

(54) DISPLAY DEVICE

(71) Applicant: LG ELECTRONICS INC., Seoul (KR)

(72) Inventors: Yijun SO, Seoul (KR); Choonhwa LEE, Seoul (KR); Dongyoup HAN, Seoul (KR); Byeonggi MOON, Seoul (KR)

(73) Assignee: LG ELECTRONICS INC., Seoul (KR)

(21) Appl. No.: 19/262,532

(22) Filed: Jul. 8, 2025

(30) Foreign Application Priority Data
Oct. 8, 2024 (WO) PCT/KR2024/015311

(51) Int. Cl. H05K 5/02

(52) U.S. Cl. CPC H05K 5/0247

(57) ABSTRACT

Provided is a display device including a display module, a cover bottom coupled to a rear surface of the display module, a control module positioned on a rear surface of the cover bottom, a back cover covering the control module and fastened to the rear surface of the cover bottom, and a cable accommodation module formed on a rear surface of the back cover, wherein a connection cable is seated on the cable accommodation module, wherein the cable accommodation module includes a plurality of cable ribs extending in a first direction and arranged in parallel with each other by being spaced apart from each other in a second direction perpendicular to the first direction, and a cable fixing portion constructed to prevent the connection cable inserted into a cable path between the plurality of cable ribs from being deviated from the cable path.

This application claims the benefit of PCT International Application No. PCT/KR2024/015311, filed on Oct. 8, 2024, which is hereby incorporated by reference as if fully set forth herein.

### BACKGROUND

### Field

The present disclosure relates to a display device that may stably fix a cable to a rear surface thereof.

### Discussion of the Related Art

With growth of information society, demand for various display devices has increased. In order to satisfy such demand, in recent years, a liquid crystal display (LCD), a field emission display (FED), a plasma display panel (PDP), and an electroluminescent device have been developed as display devices.
A liquid crystal panel of the liquid crystal display includes a liquid crystal layer and a TFT substrate and a color filter substrate opposite each other in the state in which the liquid crystal layer is interposed therebetween, wherein a picture is displayed using light provided from a backlight unit.

Recently, because an element such as an OLED emits light by itself without a backlight structure on a rear surface, a flexible display module may be realized, thereby implementing a curved display device.

As a thickness of the display module becomes smaller, enlargement and weight reduction of the display device are in progress. As the display device becomes thinner and larger, there is a need for a small and light component.

Recently, the display device is installed such that a rear surface thereof is in close contact with a wall surface. Therefore, there is insufficient space for placing a connection cable between the wall surface and a back cover of the display device, and a task of fixing the cable to a bracket or the like using a cable tie or the like is required to organize the cable. However, the cable tie or the like may have a weak fixing force or may act as a factor that hinders the close contact between the display device and the wall.

### SUMMARY

The present disclosure is to provide a display device including a cable accommodation module that may stably fix a cable.

Provided is a display device including a display module, a cover bottom coupled to a rear surface of the display module, a control module positioned on a rear surface of the cover bottom, a back cover covering the control module and fastened to the rear surface of the cover bottom, and a cable accommodation module formed on a rear surface of the back cover, wherein a connection cable is seated on the cable accommodation module, wherein the cable accommodation module includes a plurality of cable ribs extending in a first direction and arranged in parallel with each other by being spaced apart from each other in a second direction perpendicular to the first direction, and a cable fixing portion constructed to prevent the connection cable inserted into a cable path between the plurality of cable ribs from being deviated from the cable path.

The display device may further include a holder fastening hole defined in the back cover, and the cable fixing portion may include a holder plate extending in the second direction, positioned at the rear of the plurality of cable ribs, and fastened to the back cover, and a holder hook protruding from the holder plate and fixed to the holder fastening hole.

The holder hook may include a plurality of hooks, and protruding directions of locking protrusions of the plurality of holder hooks may be different from each other.

The cable accommodation module may include a cable recess recessed while forming a step in a forward direction from the back cover, the cable rib may protrude in a rearward direction from the cable recess, the holder fastening hole may include a first holder fastening hole defined in a stepped portion positioned in the second direction of the cable recess, and the holder hook may include a first holder hook positioned at an end of the holder plate in the second direction and inserted into the first holder fastening hole.

The first holder hook may include a pair of first holder hooks disposed at both ends of the holder plate in the second direction, and lengths of the pair of first holder hooks may be different from each other.

The display device may further include a cutout defined in at least one of the plurality of cable ribs, the holder fastening hole may include a second holder fastening hole positioned in front of the cutout, and the holder hook may include a second holder hook inserted into the second holder fastening hole and including a side rail inserted into the cutout.

The holder plate may include a rib groove defined in a front surface thereof and in contact with the cable rib.

The cable fixing portion may include a fixing elastic portion protruding from the cable rib toward the cable path and including a curved surface bent forward.

The display device may further include an injection hole defined in the cable path in front of a portion where the fixing elastic portion is formed.

The display device may further include a holder latch protruding from a rear end of the cable rib in the second direction, and the display device may include an injection hole defined in the cable path in front of a portion where the holder latch is formed.

The first direction may be a horizontal direction and the second direction may be an upward direction, and
the holder latch and the injection hole may be formed at a lower side of the cable path.

A first holder latch formed in a first cable path may be disposed to be misaligned with a second holder latch of a second cable path adjacent to the first cable path in the second direction while forming a predetermined spacing therefrom in the first direction.

The display device may further include an insertion groove positioned above the holder latch and recessed forward into the cable rib.

The cable fixing portion may include a plurality of inclined fixing portions, each protruding from the cable rib toward the cable path.

The cable fixing portion may include a plurality of fixing protrusions protruding from the cable rib toward the cable path and spaced apart from each other in the first direction, and
the plurality of fixing protrusions neighboring in the first direction may be arranged such that fixing protrusions having different amounts of protrusion are alternately arranged.

The display device of the present disclosure may stably fix the connection cable located on the rear surface thereon to the back cover.

In addition, the display device of the present disclosure may provide the holder structures of various sizes in which the connection cables having the various thicknesses may be inserted.

Effects obtainable from the present disclosure may be non-limited by the above-mentioned effects. And, other unmentioned effects can be clearly understood from the following description by those having ordinary skill in the technical field to which the present disclosure pertains.

### BRIEF DESCRIPTION OF THE DRAWINGS

FIG. 1 is a front perspective view showing an example of the display device according to the present disclosure;

FIG. 2 is a rear perspective view showing an example of the display device according to the present disclosure;

FIG. 3 is a view illustrating a state in which a back cover of a display device of the present disclosure is separated.

FIG. 4 shows enlarged views of portions A and Bin FIG. 3.

FIG. 5 shows an enlarged view of a portion C in FIG. 3 and a cross-sectional view illustrating a fastened state of a connection latch.

FIG. 6 is a cross-sectional view taken along a line D-D in FIG. 2.

FIG. 7 is a cross-sectional view taken along a line E-E in FIG. 2.

FIG. 8 is a cross-sectional view taken along a line F-F in FIG. 2.

FIGS. 9 and 10 are views illustrating a first embodiment of a cable accommodation module of a display device according to the present disclosure.

FIGS. 11 and 12 are views illustrating a second embodiment of a cable accommodation module of a display device according to the present disclosure.

FIG. 13 is a view illustrating a third embodiment of a cable accommodation module of a display device according to the present disclosure.

FIGS. 14 and 15 are views illustrating a fourth embodiment of a cable accommodation module of a display device of the present disclosure.

FIG. 16 is a view illustrating a fifth embodiment of a cable accommodation module of a display device according to the present disclosure.

FIG. 17 is a view illustrating a sixth embodiment of a cable accommodation module of a display device of the present disclosure.

### DESCRIPTION OF SPECIFIC EMBODIMENTS

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

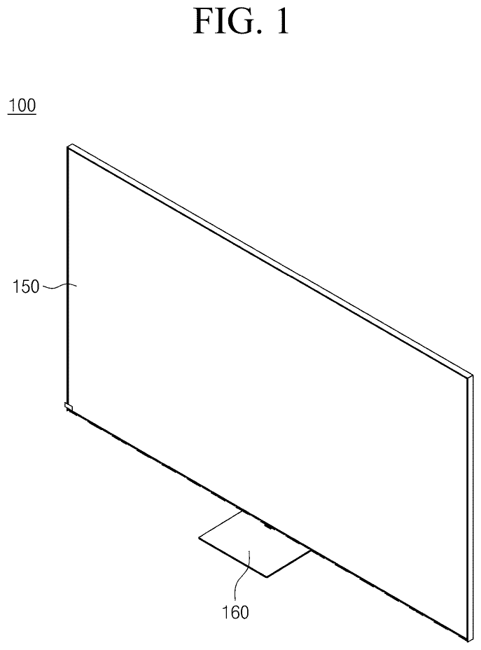

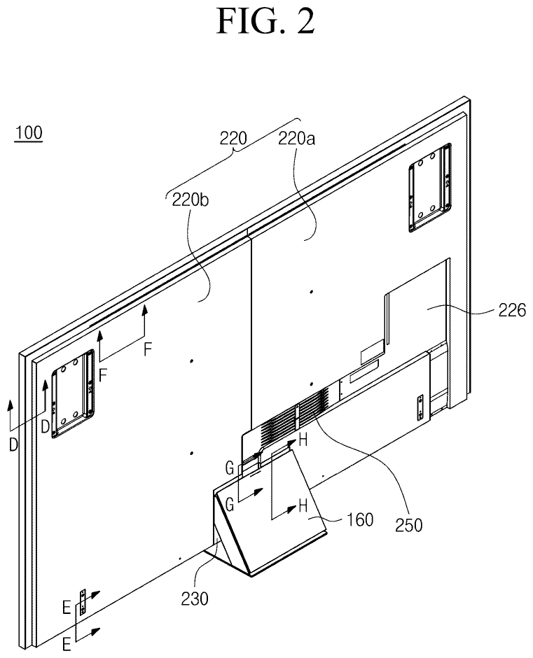

FIG. 1 is a front perspective view illustrating an example of a display device 100, and FIG. 2 is a rear perspective view. As an example of the display device 100, the display device 100 of a large screen having a small thickness is illustrated.

Recently, the display device 100 has been decreased in thickness but increased in size, so that a component thereof is required to have rigidity based on the great size of the device while having a small size. In line with such trend, each component tends to be thinner and miniaturized, but structural improvement thereof is required to ensure the rigidity.

Recently, in a display module 150, as a size of a non-display area located around a display area of a screen has decreased, a bezel has decreased, and a ratio of the screen to the size of the display device 100 has increased. A bezel-less design that seems to have almost no bezel is also being released, and an edge casing that covers a periphery of the display device and forms a side perimeter outer appearance is also able to be formed in a shape that covers only a lower portion without covering upper and left and right portions of a front surface.

The display module 150 may have a structure of a plurality of layers composed of a cover bottom 240 positioned on a rear surface thereof and a back cover 220 that forms a rear surface outer appearance of the device while covering various components including a main substrate coupled to a rear surface of the cover bottom 240.

To maintain and repair a control module 180 located on the rear surface of the cover bottom 240, it is necessary to separate the back cover 220 from the cover bottom 240. Accordingly, a coupling structure for fastening the back cover 220 to the cover bottom 240 requires a structure that enables the separation of the components while having a fixing force.

To separate the back cover 220 when inspecting the control module 180 of the display device 100, it is necessary to mount a front surface of the display device 100 facing the floor. Thereafter, a stand assembly 160 coupled to the back cover 220 may be separated from the back cover 220, and the back cover 220 may be separated from the cover bottom 240.

However, as the size of the display device 100 has increased recently, it is difficult to secure a space for seating the display device 100 on the floor indoors. In addition, there is a risk of damage when the front surface of the display module faces the floor surface.

To solve the above problem, the present disclosure provides a rear surface structure of the display device 100 capable of separating the back cover 220 without separating the stand assembly 160. The control module 180 on the rear surface of the cover bottom 240 may be replaced or repaired while the display device 100 of the present disclosure is standing in a vertical direction.

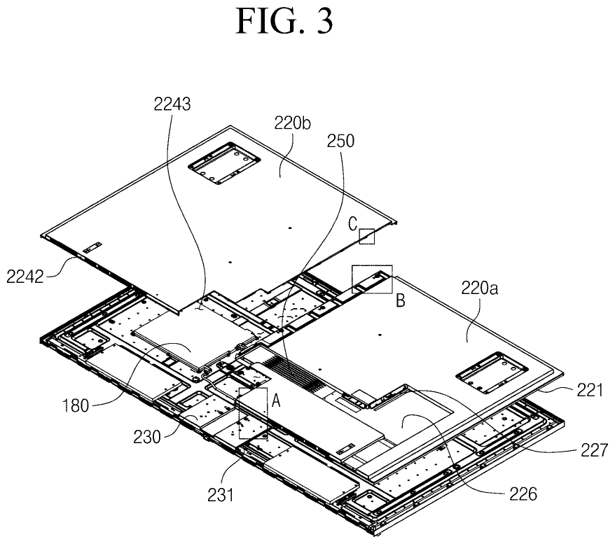

FIG. 3 is a view illustrating a state in which the back cover 220 of the display device 100 of the present disclosure is separated. A rear cover structure of the display device 100 of the present disclosure may be composed of the back cover 220 covering a first area in which the control module 180 is seated and a fixing cover 230 located in a second area to which the stand assembly 160 is fastened.

The fixing cover 230 may be fastened using a screw or the like to have a structure that has a strong fastening force and is not easily separated. The back cover 220 may use a locking structure that enables coupling and separation of components when a predetermined force is applied, such as a latch or a holder.

Although an embodiment in which only one stand assembly 160 is disposed at a center of the display device 100 is shown in FIGS. 2 and 3, a pair of stand assemblies 160 may be disposed to be spaced apart from each other in a left and right direction. In this case, a pair of fixing covers 230 may also be disposed to correspond to the number of stand assemblies 160.

Alternatively, in the case of the display device 100 supported by the pair of stand assemblies 160, after a temporary stand assembly 160 is fastened to the fixing cover 230, the existing stand assembly 160 may be separated to separate the back cover 220 while the display device 100 is standing.

The back cover 220 of the display device 100 of the present disclosure may be composed of two pieces as shown in FIG. 3 in consideration of ease of manufacturing, transportation, and assembly. A first back cover 220a and a second back cover 220b may be arranged adjacent to each other in a left and right direction, and the fixing cover 230 may be positioned between the first back cover 220a and the second back cover 220b.

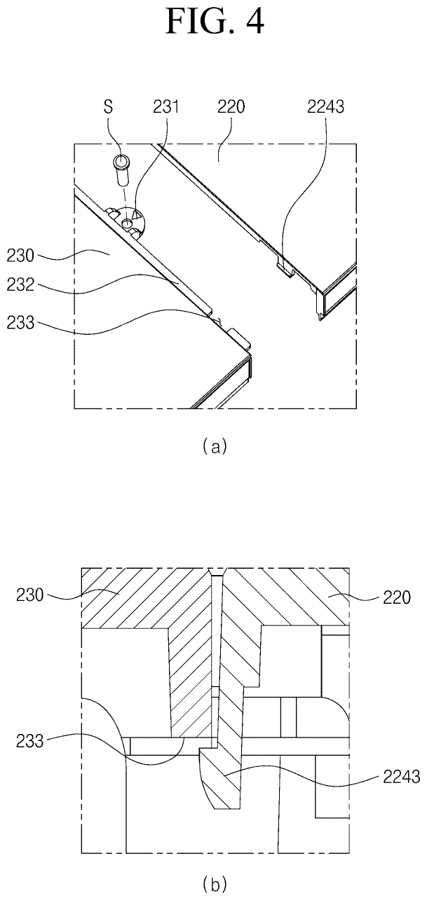

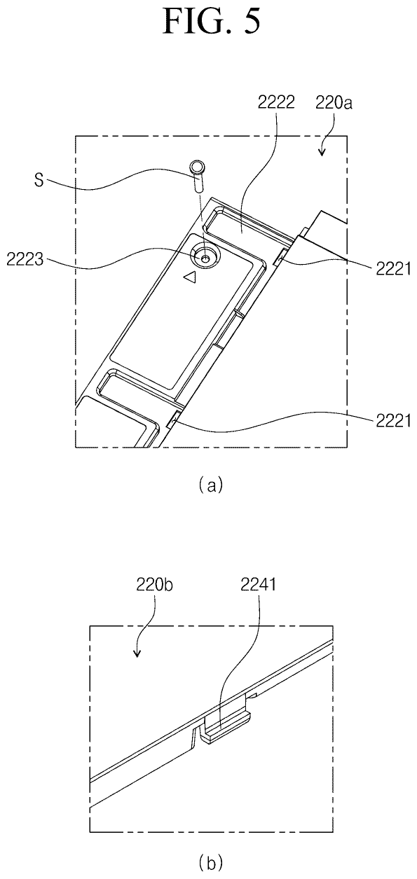

FIG. 4 shows an enlarged view of a portion A in FIG. 3 and a cross-sectional view illustrating a fastened state of a connection latch 2243, and FIG. 5 shows enlarged views of portions B and C in FIG. 3.

First, the fixing cover 230 is fastened to the cover bottom 240 using a screw S. Thereafter, the first back cover 220a may be fastened to the cover bottom 240, and the second back cover 220b may be fastened thereto. The fixing cover 230 is able to be fastened using the screw S for the fixing force of the stand assembly 160, and an embodiment in which the screws S are fastened to four places of the present disclosure is illustrated.

The first back cover 220a and the second back cover 220b may be coupled to the cover bottom 240 and the fixing cover 230 using latch structures 2241, 2242, and 2243 and a holder structure 223. Referring to (a) in FIG. 4, the back cover 220 may include a connection latch 2243 fastened to a latch locking portion 233 formed at an end of the fixing cover 230 fastened ahead.

The latch locking portion 233 may be disposed so as not to overlap a screw fastening portion 231 of the fixing cover 230. As shown in (a) in FIG. 4, an overlapping rib 232 may protrude from an edge area of the fixing cover 230 except for the latch locking portion 233 so as to overlap the back cover 220.

Referring to FIG. 5, an overlapping portion 222 of the first back cover 220a is illustrated. The first back cover 220a may include the overlapping portion 222 positioned in front of the second back cover 220b such that a connection portion between the first back cover 220a and the second back cover 220b is not opened and exposed.

As shown in (a) in FIG. 5, the second back cover 220b may be seated on a rear surface of the overlapping portion 222 of the first back cover 220a that is first coupled. A middle latch hole 2221 defined in the overlapping portion 222 of the first back cover 220a may be included, and as illustrated in (b) in FIG. 5, the second back cover 220b may include a middle latch 2241 inserted into an edge forming a boundary with the first back cover 220a.

The middle latch hole 2221 may be located at a boundary between the overlapping portion 222 and an exposed portion of the first back cover 220a, and may include a latch guide 2222 extending from an end of the overlapping portion 222 to the middle latch hole 2221 such that the middle latch 2241 is fastened to the middle latch hole 2221.

To prevent the first back cover 220b from being separated together when separating the second back cover 220a by releasing the middle latch 2241 fastened to the middle latch hole 2221, the overlapping portion 222 of the first back cover 220a may be fastened to the cover bottom 240 via the screw S.

Because a screw hole 2223 defined in the overlapping portion 222 of the first back cover 220a is covered by the second back cover 220b and is not exposed to the outside, the screw is not exposed to the outside of the display device 100 even when the fastening is achieved using the screw.

Locations of the first back cover 220a and the second back cover 220b may be interchanged. However, because it is easier to separate the second back cover 220b than the first back cover 220a coupled first, the control module 180 positioned in front of the first back cover 220a may have a component having a lower risk of failure than the control module 180 positioned in front of the second back cover 220b.

The first back cover 220a may include a terminal hole 227 through which a connection terminal is exposed. A connection cable for connection with an external device may be fastened to the connection terminal exposed through the terminal hole.

In addition, the first back cover 220a may include a cable accommodation module 250 for placing the connection cable. To prevent occurrence of a gap between the rear surface of the display device 100 and a wall caused by the connection cable located in the cable accommodation module 250, a cable recess 226 recessed forward in the rear surface of the first back cover 220a may be included.

When the connection cable is disposed in the cable accommodation module 250, because a load may be applied to the first back cover 220a because of a weight of the connection cable, a fastening force may be increased using the screw.

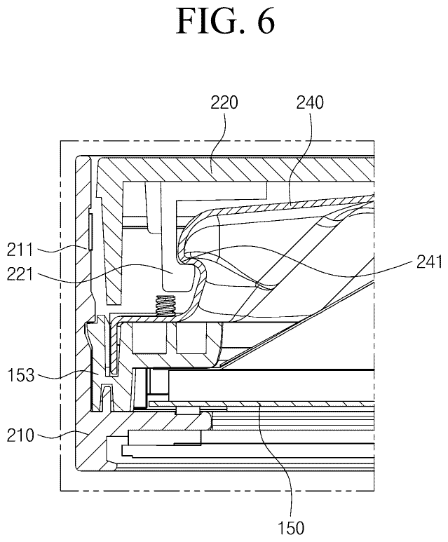

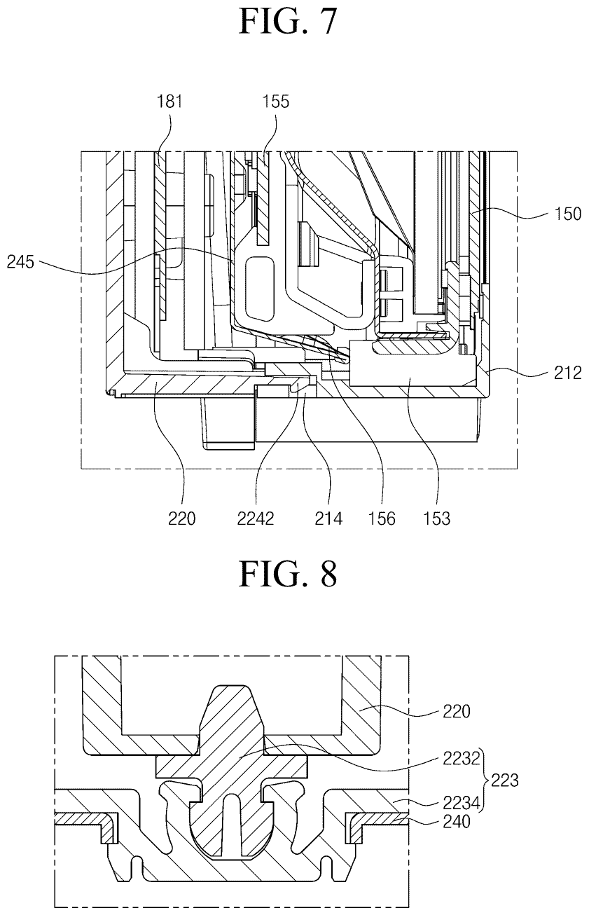

FIG. 6 is a cross-sectional view taken along a line D-D in FIG. 2, and FIG. 7 is a cross-sectional view taken along a line E-E in FIG. 2. FIG. 6 illustrates an edge portion at each of left and right sides of the display device 100. The back cover 220 may include an edge protrusion 221 inserted into a locking groove 241 defined at an edge of the cover bottom 240.

After the edge protrusion 221 of a lateral end of the first back cover 220a is inserted into the cover bottom 240, the overlapping portion 222 may be fastened with the screw S, and the connection latch 2243 may be fastened to the latch locking portion 233 of the fixing cover 230. After an edge protrusion of a lateral end of the second back cover 220b is inserted into the cover bottom 240, the middle latch 2241 may be inserted into the latch groove, and the connection latch 2243 may be fastened to the latch locking portion 233 of the fixing cover 230.

An edge casing 211 surrounding an outer periphery of the display device 100 is also referred to as a casing top and includes a structure exposed to the outside of the display device 100.

Because a side of the display device 100 may be exposed to the outside, the back cover 220 may be located inward of the edge casing 211 to construct the side surface of the display device 100 as one continuous member. The edge casing 211 may not be directly fastened to the back cover 220, and the edge casing 211 may be indirectly coupled thereto by being fastened with a guide panel 153 of the display module 150.

As illustrated in FIG. 7, a lower edge casing 212 constituting a lower portion of the display device 100 may cover a portion of the front surface of the display device 100, unlike the side surface. A lower end of the display module 150 requires a space through which a flexible substrate 156 for connection with a panel substrate 155 located on a rear surface of the module passes, so that even when the bezel-less design is implemented in the side or upper portion, the lower end needs to be partially covered.

The lower edge casing 212 may include a front portion positioned on the front surface of the display device 100 and a lower portion positioned at a lower portion. Because a load may be applied to the lower portion of the display device 100 in a direction of gravity when the device is mounted, a gap may occur between the back cover 220 and the edge casing 211, and thus, a latch structure may be equipped. A bottom latch 2242 formed at a lower portion of the back cover 220 may be included so as to be inserted into a bottom latch hole 214 defined in the edge casing 211.

FIG. 8 is a cross-sectional view taken along a line F-F in FIG. 2. As the size of the display device 100 increases, it is difficult to secure the fixing force only with the latch structures 2241, 2242, and 2243 located at the edges of the back cover 220, so that a holder module 223 located in the middle of the back cover 220 may be included.

The holder module 223 may be composed of a first holder 2234 positioned on the rear surface of the cover bottom 240 and a second holder 2232 positioned on the front surface of the back cover 220, and may be coupled or separated by applying a force of a predetermined magnitude or greater using an elastic material. The holder module 223 may be disposed to be spaced apart from the latches 2241, 2242, and 2243 to stably fix a portion of the back cover 220 having insufficient fastening force.

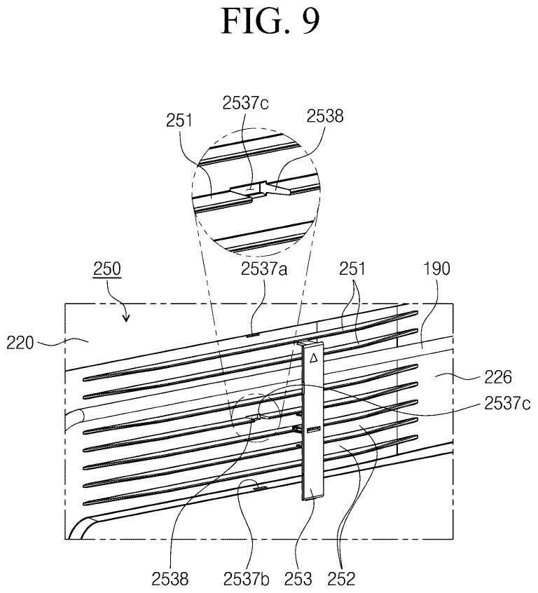

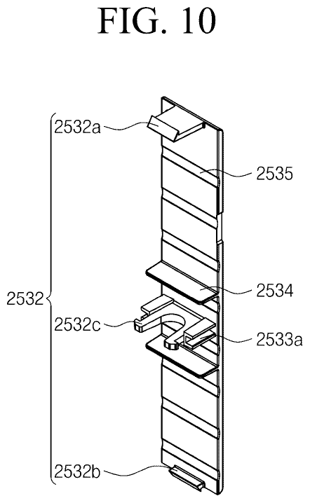

The rear surface of the display device 100 may include a cable accommodation module 250 on which a connection cable 190 for connecting power or transmitting and receiving data to and from an external device is seated. FIGS. 9 and 10 are views illustrating a first embodiment of the cable accommodation module 250 of the display device 100 according to the present disclosure.

The cable accommodation module 250 may include a cable recess 226 recessed forward from a rear surface of the back cover 220 such that a gap between the connection cable 190 and the wall is not widened. The cable accommodation module 250 may include a cable rib 251 such that the cable may be located in the cable recess 226.

The cable ribs 251 may extend along a first direction that is an extension direction of the connection cable 190 and may be arranged to be spaced apart from each other in a second direction perpendicular to the first direction. A cable path 252 through which the cable passes may be defined in a separation space between a pair of cable ribs 251, and the number of cable paths 252 may be one smaller than the number of cable ribs 251. In the present embodiment, the first direction may be a horizontal direction and the second direction may be a vertical direction.

The connection cables 190 having different thicknesses may be disposed via different spacings between the cable ribs 251. The cable rib 251 of the present disclosure may be constructed such that the connection cable 190 is easily inserted into the cable path 252 by including an inclination in which a central portion protrudes the most and an amount of protrusion decreases in directions of both ends.

In addition, the cable rib 251 may be constructed to have a portion connected to the back cover 220 (the cable recess 226) having the greatest thickness and become thinner toward a rear end, so that an inlet of the cable path 252 may be wide.

Although a terminal shape of the connection cable 190 is standardized, the thickness is different for each product, so that it is difficult for the cable path 252 to be accurately manufactured based on the size of each connection cable 190. Therefore, it is difficult to allow the connection cable 190 to be in close contact with the back cover 220 only with the cable rib 251.

In the present embodiment, a holder plate 253 fastened from the rear of the cable rib 251 after the connection cable 190 is inserted into the cable path 252 may be used. The holder plate 253 may be disposed such that the second direction perpendicular to the first direction, which is the extension direction of the cable rib 251, becomes a longitudinal direction, and may have a shape crossing the plurality of cable paths 252.

A length of the holder plate 253 may correspond to a length of the cable recess 226 in the second direction, and may be coplanar with the rear surface of the back cover 220 when fastened.

The holder plate 253 may include a holder hook 2532 inserted into a holder fastening hole 2537a, 2537b, and 2537c defined in the back cover 220 and protruding forward. The holder hook 2532 may include a plurality of holder hooks, and in the present embodiment, the plurality of holder hooks may be located at both sides and a center in the longitudinal direction (the second direction).

The plurality of holder hooks 2532 may include locking protrusions protruding in different directions to increase a fastening force. The locking protrusions of a pair of first holder hooks 2532a and 2532b located at both ends of the second direction may face in opposite directions (upper and lower sides), and a second holder hook 2532c located at the center may include a pair of locking protrusions protruding to both sides (left and right sides) of the first direction.

The pair of first holder hooks 2532a and 2532b may include first holder fastening holes 2537a and 2537b defined in stepped portions positioned at both sides of the cable recess 226 in the second direction. The first holder fastening holes 2537a and 2537b may be defined in a wall surface of the cable recess 226 or may be defined in a seating surface of the cable recess 226.

When the locations of the first holder fastening holes 2537a and 2537b are different, lengths of the first holder hooks 2532a and 2532b may be different from each other. As illustrated in FIG. 10, after inserting the long first holder hook 2532a into the first holder fastening hole 2537a located at an inner side of the cable recess 226 first, the short first holder hook 2532b may be fastened to the first holder fastening hole 2537b located at an outer side to easily fasten the holder plate 253 to the back cover 220.

In one example, because the second holder hook 2532c protrudes from the center of the holder plate 253, it may be disposed to overlap one of the plurality of cable ribs 251 so as not to overlap the cable path 252. As illustrated in FIG. 9, the cable rib 251 may be partially cut 2538 to define a second holder fastening hole 2537c to which the second holder hook 2532c is fastened.

A side rail 2533 into which the cutout 2538 of the cable rib 251 is inserted may be included such that the second holder hook 2532c is easily inserted into the second holder fastening hole 2537c.

The holder plate 253 may include a rib groove 2535 in contact with the rear end of the cable rib 251 so as to be in close contact with the cable rib 251. A rib guide 2534 protruding above or below (in the second direction) of the rib groove 2535 may be included.

The rib guide 2534 may help the holder plate 253 to be coupled such that the holder hook 2532 of the holder plate 253 is inserted into a holder coupling portion, and at the same time, may prevent the holder plate 253 from sagging.

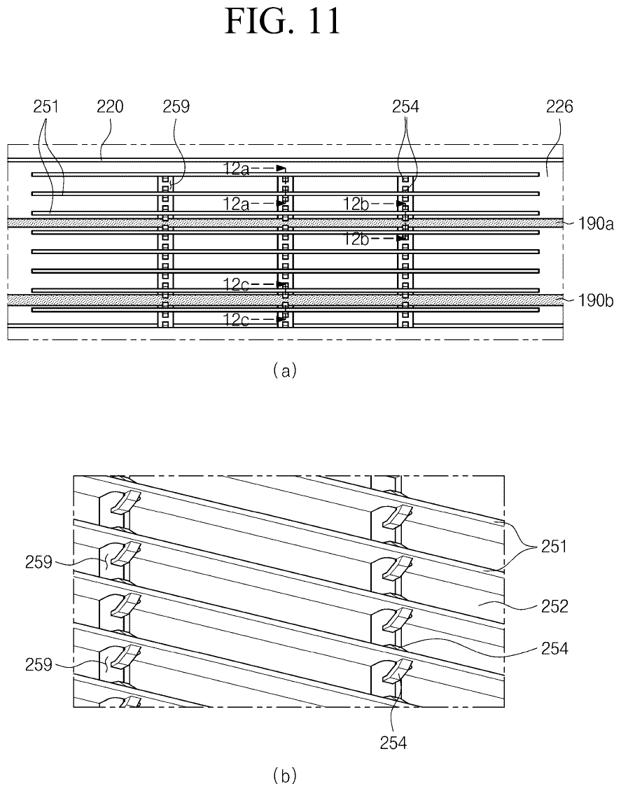

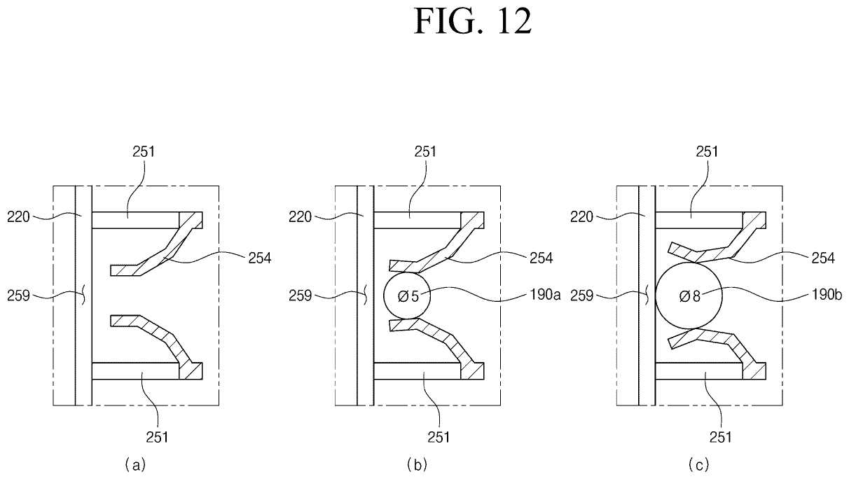

FIGS. 11 and 12 are views illustrating a second embodiment of the cable accommodation module 250 of the display device 100 according to the present disclosure. (a) in FIG. 11 is a rear view of the second embodiment of the storage module 250, and (b) in FIG. 11 is a perspective view. (a) in FIG. 12 is a cross-sectional view taken along a line 12a-12a in FIG. 11, and (b) and (c) are cross-sectional views taken along a line 12b-12b and a line 12c-12c in FIG. 11, showing a state in which the connection cables 190 having different thicknesses are accommodated in the accommodating module 250.

The present embodiment may include a fixing elastic portion 254 to fix the connection cable 190 in the cable path 252. As shown in (a) in FIG. 12, the fixing elastic portion 254 may include a curved surface protruding from the cable rib 251 toward the cable path 252 and bent forward.

When the connection cable 190 is pushed into the cable path 252 on the rear surface of the back cover 220, the fixing elastic portion 254 may be bent corresponding to the shape of the connection cable 190 to hold the connection cable 190.

As illustrated in (b) and (c) in FIG. 12, even though the diameters of the connection cables 190 are different from each other, the fixing elastic portion 254 may maintain the state of being in contact with the connection cable 190, thereby preventing the connection cable 190 from deviating from the cable path 252.

The fixing elastic portions 254 may protrude symmetrically at both sides of the cable path 252 as shown in FIG. 11, or may be formed only at one side. When formed only at one side, the fixing elastic portion 254 may fix the connection cable 190 by pressing the connection cable 190 in a direction of the cable rib 251 where the fixing elastic portion 254 is not formed.

Because the back cover 220 is manufactured via injection-molding, it is difficult to integrally form a curved component such as the fixing elastic portion 254. Accordingly, an injection hole 259 into which an injection mold may be inserted may be included in front of the cable path 252 corresponding to a location where the fixing elastic portion 254 is formed (see (b) in FIG. 11).

As illustrated in FIG. 11, the injection holes 259 may be connected to each other in the second direction, and when the fixing elastic portion 254 is formed only at one side of the cable rib 251, the injection hole 259 may be defined only in an area in front of a portion where the fixing elastic portion 254 is formed.

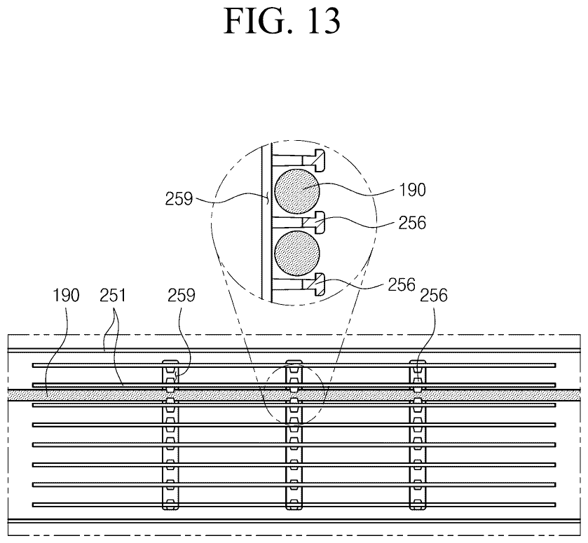

FIG. 13 is a view illustrating a third embodiment of the cable accommodation module 250 of the display device 100 according to the present disclosure. In the present embodiment, unlike fixing the connection cable 190 in direct contact with the connection cable 190 like the fixing elastic portion 254, a holder latch 256 protruding in the second direction may be formed at the inlet.

The holder latches 256 may be formed on both of a pair of cable ribs 251 positioned on both sides of the cable path 252 as shown in FIG. 13, or may be formed only on one side. The plurality of holder latches 256 may have different amounts of protrusion so as to be applied to all the connection cables 190 having the different diameters.

As shown in FIG. 13, the plurality of holder latches 256 may be arranged to be spaced apart from each other at a predetermined spacing in the horizontal direction. For injection-molding of the holder latch 256, an injection hole 259 for an injection mold to be inserted may be defined in the rear surface.

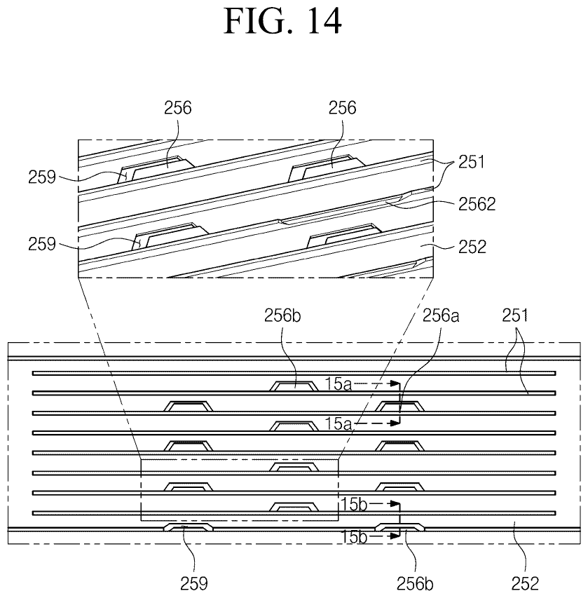

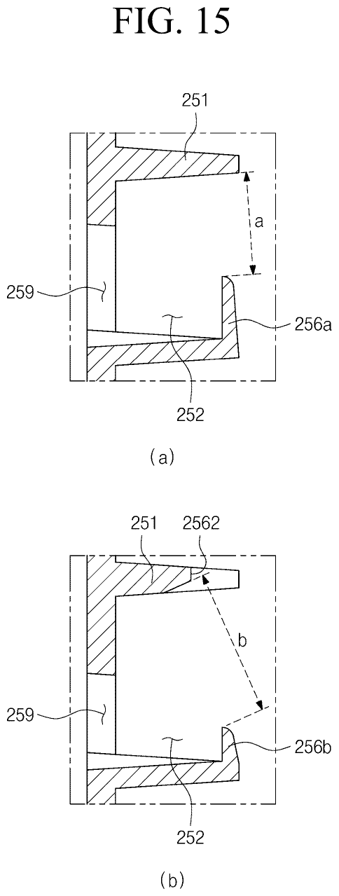

FIGS. 14 and 15 are views illustrating a fourth embodiment of the cable accommodation module 250 of the display device 100 according to the present disclosure. As shown in FIG. 14, the holder latch 256 may be formed only at a lower side corresponding to a gravity direction.

After the connection cable 190 is inserted into the cable path 252 of the present embodiment, the connection cable 190 may be caught by the holder latch 256 and may not be deviated from the cable path 252. When the holder latch 256 protruding only from one side of the cable path 252 is included, as shown in FIG. 14, a size of the injection hole 259 may be small, thereby securing rigidity of the back cover 220.

When the injection hole 259 is defined to be long in one direction, the rigidity of the back cover 220 may be problematic, and thus, as illustrated in FIG. 14, it may be defined to be spaced apart in the first direction from the holder latch 256 of the cable path 252 neighboring thereto in the second direction without being disposed side by side in the second direction. That is, the plurality of holder latches 256 may be arranged in a zigzag manner.

(a) in FIG. 15 is a cross-sectional view of a cable path 252 for a connection cable 190a having a small diameter, and (b) in FIG. 15 is a cross-sectional view of a cable path 252 for a connection cable 190b having a large diameter. As shown in (b) in FIG. 15, when a holder latch 256b is formed to be small like a holder latch 256a for the connection cable 190a having the small diameter, the connection cable 190 having the large diameter may also be inserted into the cable path 252.

When necessary, an upper cable rib 251 of a portion where the holder latch 256 is formed may include an insertion groove 2562 recessed forward from a rear end such that the connection cable 190 having a larger diameter may be inserted. When the insertion groove 2562 is defined, a size ‘b’ of the inlet of the cable path 252 may be secured to be great, so that the connection cable 190 having the large diameter may be inserted (b>a).

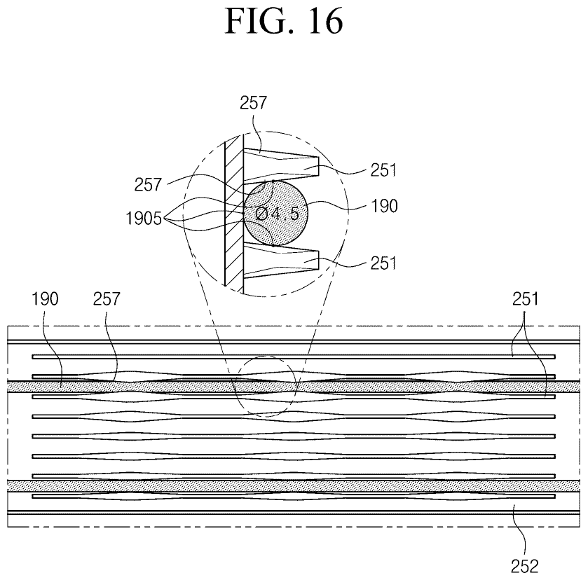

FIG. 16 is a view illustrating a fifth embodiment of the cable accommodation module 250 of the display device 100 according to the present disclosure. A cable fixing portion of the present embodiment may form an inclined fixing portion 257 such that the thickness of the cable rib 251 changes. The inclined fixing portion 257 may have a shape of protruding in the first direction while drawing an S shape and being recessed, and the connection cable 190 may be inserted and fixed to a section having a small width in the second direction of the cable path 252 via the inclined fixing portion 257.

The inclined fixing portion 257 may be inclined in the first direction, and may be inclined in a thickness direction of the display device 100 (a front and rear direction) at the same time. When a width of a rear end of the cable path 252 is slightly greater than that of a front end, even when the diameter of the connection cable 190 is slightly greater, the connection cable 190 may be inserted into and fixed to the inclined fixing portion 257.

The connection cables 190 of various diameters may be seated by varying an amount of protrusion of the inclined fixing portion 257 for each cable path 252. An amount of protrusion of an inclined fixing portion 257 located at a lower side of the drawing is small, so that the inclined fixing portion 257 located at the lower side may correspond to a connection cable 190 having a greater diameter.

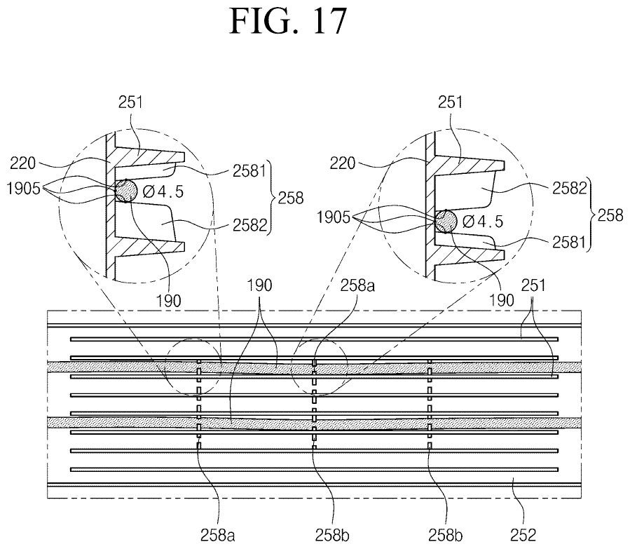

FIG. 17 is a view illustrating a sixth embodiment of the cable accommodation module 250 of the display device 100 according to the present disclosure. A cable fixing portion of the cable accommodation module 250 of the present embodiment may include a fixing protrusion 258 protruding from the cable rib 251 in the second direction.

The fixing elastic portion 254 of the above-described embodiment in FIG. 11 has the curved surface bent forward for the elasticity, but the present embodiment extends in the vertical direction. Therefore, there is an advantage in that it is not necessary to define the injection hole 259 in the back cover 220 to form the fixing protrusion 258 of the present embodiment.

The fixing protrusion 258 may be constructed to make a three-point contact 1905 with the connection cable 190, may protrude only from the cable rib 251 at one side, or may include a fixing protrusion 2581 and a second fixing protrusion 2582 protruding to face each other as shown in FIG. 17.

When the connection cable 190 is disposed to be linear in the first direction, the connection cable 190 may slide, so that heights of the fixing protrusions 258 adjacent to each other in the first direction may be different such that the connection cable 190 is seated on the cable path 252 while forming an S-shape.

When the pair of fixing protrusions 2581 and 2582 protruding from both sides are equipped as a set as shown in FIG. 17, the pair of fixing protrusions 2581 and 2582 may have a first spacing therebetween, but amounts of protrusion of fixing protrusions 258 adjacent thereto in the first direction may vary alternately, so that the connection cable 190 may be disposed while forming the S shape.

As described above, the display device 100 of the present disclosure may stably fix the connection cable 190 located on the rear surface thereof to the back cover 220.

In addition, the display device 100 of the present disclosure may provide the cable accommodating modules 250 of various sizes into which the connection cables 190 of the various thicknesses may be inserted.

In addition, the display device 100 of the present disclosure may provide the simple outer appearance structure via the fastening without the screw structure exposed to the outside.

The above detailed description should not be construed as being limitative in all terms, but should be considered as being illustrative. The scope of the present invention should be determined by reasonable analysis of the accompanying claims, and all changes in the equivalent range of the present invention are included in the scope of the present invention.

What is claimed is:

1. A display device comprising:
a display module;
a cover bottom coupled to a rear surface of the display module;
a control module positioned on a rear surface of the cover bottom;
a back cover covering the control module and fastened to the rear surface of the cover bottom; and
a cable accommodation module formed on a rear surface of the back cover, wherein a connection cable is seated on the cable accommodation module,
wherein the cable accommodation module includes:
a plurality of cable ribs extending in a first direction and arranged in parallel with each other by being spaced apart from each other in a second direction perpendicular to the first direction; and
a cable fixing portion constructed to prevent the connection cable inserted into a cable path between the plurality of cable ribs from being deviated from the cable path.

2. The display device of claim 1, further comprising a holder fastening hole defined in the back cover,
wherein the cable fixing portion includes:
a holder plate extending in the second direction, positioned at the rear of the plurality of cable ribs, and fastened to the back cover; and
a holder hook protruding from the holder plate and fixed to the holder fastening hole.

3. The display device of claim 2, wherein the holder hook includes a plurality of hooks,
wherein protruding directions of locking protrusions of the plurality of holder hooks are different from each other.

4. The display device of claim 2, wherein the cable accommodation module includes a cable recess recessed while forming a step in a forward direction from the back cover,
wherein the cable rib protrudes in a rearward direction from the cable recess,
wherein the holder fastening hole includes a first holder fastening hole defined in a stepped portion positioned in the second direction of the cable recess,
wherein the holder hook includes a first holder hook positioned at an end of the holder plate in the second direction and inserted into the first holder fastening hole.

5. The display device of claim 4, wherein the first holder hook includes a pair of first holder hooks disposed at both ends of the holder plate in the second direction,
wherein lengths of the pair of first holder hooks are different from each other.

6. The display device of claim 2, further comprising a cutout defined in at least one of the plurality of cable ribs,
wherein the holder fastening hole includes a second holder fastening hole positioned in front of the cutout,
wherein the holder hook includes a second holder hook inserted into the second holder fastening hole and including a side rail inserted into the cutout.

7. The display device of claim 2, wherein the holder plate includes a rib groove defined in a front surface thereof and in contact with the cable rib.

8. The display device of claim 1, wherein the cable fixing portion includes a fixing elastic portion protruding from the cable rib toward the cable path and including a curved surface bent forward.

9. The display device of claim 8, further comprising an injection hole defined in the cable path in front of a portion where the fixing elastic portion is formed.

10. The display device of claim 1, further comprising a holder latch protruding from a rear end of the cable rib in the second direction,
wherein the display device includes an injection hole defined in the cable path in front of a portion where the holder latch is formed.

11. The display device of claim 10, wherein the first direction is a horizontal direction and the second direction is an upward direction,
wherein the holder latch and the injection hole are formed at a lower side of the cable path.

12. The display device of claim 11, wherein a first holder latch formed in a first cable path is disposed to be misaligned with a second holder latch of a second cable path adjacent to the first cable path in the second direction while forming a predetermined spacing therefrom in the first direction.

13. The display device of claim 11, further comprising an insertion groove positioned above the holder latch and recessed forward into the cable rib.

14. The display device of claim 1, wherein the cable fixing portion includes a plurality of inclined fixing portions, each protruding from the cable rib toward the cable path.

15. The display device of claim 1, wherein the cable fixing portion includes a plurality of fixing protrusions protruding from the cable rib toward the cable path and spaced apart from each other in the first direction,
wherein the plurality of fixing protrusions neighboring in the first direction are arranged such that fixing protrusions having different amounts of protrusion are alternately arranged.
